(19) United States
(12) Patent Application Publication
(10) Pub. No.: US 2008/0247434 A1
(43) Pub. Date: Oct. 9, 2008

(54) SEMICONDUCTOR LIGHT-EMITTING DEVICE

(75) Inventors: Katsumi Kishino, Tokyo (JP); Ichiro Nomura, Tokyo (JP); Kunihiko Tasai, Kanagawa (JP); Koshi Tamamura, Tokyo (JP); Hiroshi Nakajima, Kanagawa (JP); Hitoshi Nakamura, Tokyo (JP)

Correspondence Address: SONNENSCHEIN NATH & ROSENTHAL LLP, P.O. BOX 061080, WACKER DRIVE STATION, SEARS TOWER, CHICAGO, IL, 60606-1080, US

(73) Assignees: SONY CORPORATION, Tokyo (JP); HITACHI, LTD, Tokyo (JP); SOPHIA SCHOOL CORPORATION, Tokyo (JP)

(21) Appl. No.: 12/059,540

(22) Filed: Mar. 31, 2008

(30) Foreign Application Priority Data
Apr. 3, 2007 (JP) 2007-097141

(51) Int. Cl. H01S 5/327

(52) U.S. Cl. 372/46.01

(57) ABSTRACT

A semiconductor light-emitting device capable of increasing the carrier concentration of a p-type cladding layer and improving light-emitting efficiency is provided. A semiconductor light-emitting device is made of a Group II-VI compound semiconductor, and the semiconductor light-emitting device includes an active layer between an n-type cladding layer and a p-type cladding layer, in which the active layer has a Type II superlattice structure, and the junctions between the active layer and the n-type cladding layer and between the active layer and the p-type cladding layer each have a Type I structure, and the p-type cladding layer includes tellurium (Te) as a Group VI element.

### CROSS REFERENCES TO RELATED APPLICATIONS

The present invention contains subject matter related to Japanese Patent Application JP 2007-097141 filed in the Japanese Patent Office on Apr. 3, 2007, the entire contents of which being incorporated herein by reference.

### BACKGROUND OF THE INVENTION

1. Field of the Invention

The present invention relates to a semiconductor light-emitting device such as a laser diode or a LED (Light Emitting Diode), and more specifically to a semiconductor light-emitting device suitable for emitting light in a green region with a wavelength of 500 nm to 600 nm.

2. Description of the Related Art

Laser diodes have been practically used in various fields as light-emitting devices with a small size and high reliability. In particular, a principal application of a laser diode emitting light in a visible to infrared region is optical recording such as optical disks, and as practically used laser diodes emitting light in a visible to infrared region, AlGaAs-based lasers (with a wavelength of 780 nm) used in CDs (Compact Discs) or the like, AlGaInP-based lasers (with a wavelength of 650 nm) used in DVDs (Digital Versatile Disks) or the like and AlGaInN-based lasers (with a wavelength of 405 nm) used in next-generation DVDs or the like are cited. Moreover, red lasers or blue lasers are increasingly used in biomedical applications or displays.

However, a laser diode emitting light in a green region (with a wavelength of 500 nm to 600 nm) has not been implemented yet.

Green lasers are widely used as laser pointers because of good visibility; however, in this case, solid-state lasers using SHG (Second Harmonic Generation) are used, and the solid-state lasers have some issues such as high cost and unstable temperature characteristics. Moreover, when green laser diodes are put into practical use in the field of display, laser diodes can be used in all of RGB light sources, and a display having advantages such as a small size, low cost and high color reproducibility can be implemented.

The development of laser diodes emitting light in a green region has been conducted in companies and research institutes by using a ZnSe-based mixed crystal which is a Group II-VI compound semiconductor. However, the material has a practically crucial issue that the material causes a short device lifetime. In E. Kato et al., Electronics Letters, IEEE, 1998, Vol. 34, p. 282, it is indicated that a ZnSe-based material has a weak junction between atoms, so crystal defects are increased during light emission.

On the other hand, it is reported in I. Nomura et al., Phys.stat.sol.(b), 2006, 243, No. 4, pp. 924-928 that a device using a Group II-VI compound semiconductor which includes beryllium (Be) on an InP substrate achieves a device lifetime of a few thousand hours. It is because it is considered that beryllium has a strong covalent bond property, so the junction between atoms is strong, and an increase in defects such as defects generated in a ZnSe-based semiconductor can be prevented.

### SUMMARY OF THE INVENTION

However, a green laser diode made of such a Group II-VI compound semiconductor which includes beryllium (Be) has the following issue.

At present, a dopant as a useful acceptor into a Group II-VI compound semiconductor is practically only nitrogen (N), and doping can be achieved by introducing radical nitrogen by an RF (Radio Frequency). Then, it is known that by radical nitrogen doping, a high carrier concentration can be obtained only in a tellurium (Te)-based mother material. On the other hand, the tellurium (Te)-based material has a high VBM (Valence Band Maximum), so in the case where the tellurium (Te)-based material is used in a p-type cladding layer, a Type II junction is easily formed between the p-type cladding layer and an active layer. Therefore, it is difficult to be compatible between an increase in the carrier concentration of the p-type cladding layer and a Type I junction. For example, in Song-Bek Che et al., Japanese Journal of Applied Physics, 2001, Vol. 40, pp. 6747-6752, as shown in FIG. 5, a laser structure in which a BeZnTe single layer film is used for a p-type cladding layer, and an active layer is made of a Type II superlattice (BeZnTe/ZnCdSe) is formed to aim for an increase in the carrier concentration of the p-type cladding layer; however, the junction between the p-type cladding layer and the active layer has a Type II structure, so light-emitting efficiency is extremely low.

To overcome the issue, in Song-Bek Che et al., Phys.stat.sol.(b), 2002, Vol. 229, No. 2, pp. 1001-1004, a superlattice of MgSe/BeZnTe is used for the p-type cladding layer to prevent the above-described Type II junction between the active layer and the p-type cladding layer. However, MgSe is an easily oxidizable material, so MgSe has poor material reliability. In particular, in T. Baron et al., Journal of Crystal Growth, (Netherlands), Elsevier Science B.V., 1998, 184/185, p. 415, it is suggested that serious material deterioration occurs in nitrogen-doped MgSe, so device reliability is poor. Moreover, a demerit such as a superlattice structure having poorer electrical characteristics than a bulk structure is considered.

In related arts, structures in which an active layer is made of a Type II superlattice are proposed (for example, Japanese Unexamined Patent Application Publication Nos. S59-172785 and H04-100292); however, in the related arts, a Group III-V compound semiconductor is used, so the basic structures are different. For example, in Japanese Unexamined Patent Application Publication No. S59-172785, an active layer is made of a GaAs/AlSb superlattice, and a cladding layer has a larger Eg than any layer of the superlattice active layer. Moreover, in Japanese Unexamined Patent Application Publication No. H04-100292, as a superlattice active layer, GaAs/GaP and GaAs/AlAs are used, and each layer is made of a binary mixed crystal, and the material of a cladding layer is a ternary mixed crystal (for example, in the case of GaAs/GaP, GaAs_{0.5}P_{0.5}) made of the binary mixed crystals used in the superlattice active layer.

In view of the foregoing, it is desirable to provide a semiconductor light-emitting device capable of increasing the carrier concentration of a p-type cladding layer and improving light-emitting efficiency.

According to an embodiment of the invention, there is provided a semiconductor light-emitting device made of a Group II-VI compound semiconductor, the semiconductor light-emitting device including an active layer between an n-type cladding layer and a p-type cladding layer, in which the active layer has a Type II superlattice structure, and the junctions between the active layer and the n-type cladding layer and between the active layer and the p-type cladding layer each have a Type I structure, and the p-type cladding layer includes tellurium (Te) as a Group VI element. The Type I means a structure in which electrons and holes are confined in a semiconductor with a small band gap, and the Type II means a structure in which a spatial position where electrons and holes are confined is different.

Moreover, the Group II-VI compound semiconductor includes at least one Group II element selected from the group consisting of zinc (Zn), magnesium (Mg), beryllium (Be) and cadmium (Cd), and at least one Group VI element selected from the group consisting of oxygen (O), sulfur (S), selenium (Se) and tellurium (Te).

In the semiconductor light-emitting device according to the embodiment of the invention, the active layer has a Type II superlattice structure, and the junction between the active layer and the p-type cladding layer has a Type I structure. Therefore, light-emitting efficiency is improved. Moreover, the p-type cladding layer includes tellurium (Te) as a Group VI element, so the carrier concentration is improved.

In the semiconductor light-emitting device according to the embodiment of the invention, the active layer has the Type II superlattice structure, and the junctions between the active layer and the n-type cladding layer and between the active layer and the p-type cladding layer each has a Type I structure, so light-emitting efficiency can be improved. Moreover, the p-type cladding layer includes tellurium (Te) as a Group VI element, so a high carrier concentration can be achieved.

Other and further objects, features and advantages of the invention will appear more fully from the following description.

### BRIEF DESCRIPTION OF THE DRAWINGS

FIG. 1 is a sectional view showing the configuration of a main part of a laser diode according to an embodiment of the invention;

FIG. 2 is an illustration showing results obtained by calculating dependence of Eg (at room temperature) of a BeₓZn₁₋ₓSe_{y}Te_{1-y} mixed crystal (0<x<1, 0<y<1) on composition ratios x and y;

FIG. 3 is an illustration showing an example of a band structure of a main part of the laser diode shown in FIG. 1;

FIG. 4 is an illustration showing another example of the band structure of the main part of the laser diode shown in FIG. 1; and

FIG. 5 is an illustration showing an example of a band structure of a main part of a laser diode in a related art.

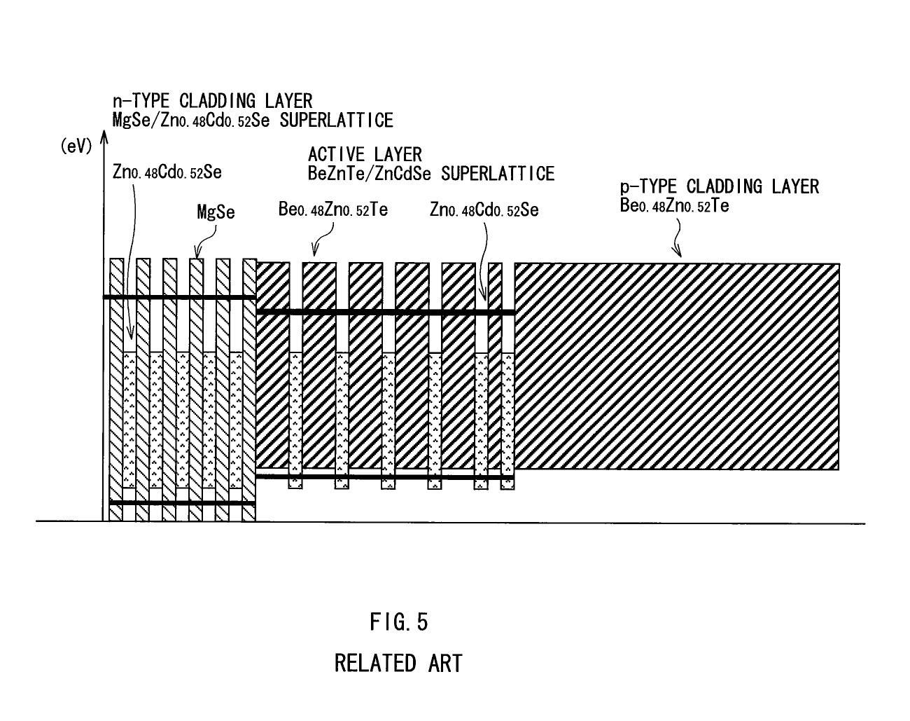

### DETAILED DESCRIPTION OF THE PREFERRED EMBODIMENTS

A preferred embodiment will be described in detail below referring to the accompanying drawings.

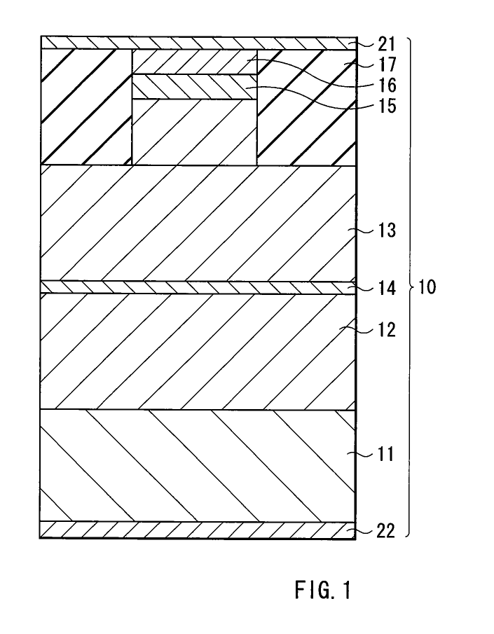

FIG. 1 shows the configuration of a main part of a laser diode according to an embodiment of the invention. A laser diode 10 is, for example, a green laser diode with a wavelength of 500 nm to 600 nm used for a laser pointer, and includes an active layer 14 between an n-type cladding layer 12 and a p-type cladding layer 13 which is made of a Group II-VI compound semiconductor. The n-type cladding layer 12, the active layer 14 and the p-type cladding layer 13 are laminated in order on a substrate 11 made of, for example, InP, and a superlattice layer 15 and a cap layer 16 are formed in order on the p-type cladding layer 13.

The n-type cladding layer 12 has, for example, a thickness in a laminate direction (hereinafter simply referred to as thickness) of 0.5 μm, and has a superlattice structure in which MgSe layers and Zn_{0.48}Cd_{0.52}Se mixed crystal layers are alternately laminated.

The p-type cladding layer 13 includes tellurium (Te) as a Group VI element. A Group II-VI compound semiconductor mixed crystal including tellurium (Te) as a Group VI element can be a p-type semiconductor having a high carrier concentration of the order of 10 to the 20th power by radical nitrogen doping. Thereby, in the laser diode 10, the carrier concentration of the p-type cladding layer 13 can be increased.

The p-type cladding layer 13 is preferably made of a single layer including tellurium (Te). It is because compared to the superlattice structure, electrical characteristics can be improved.

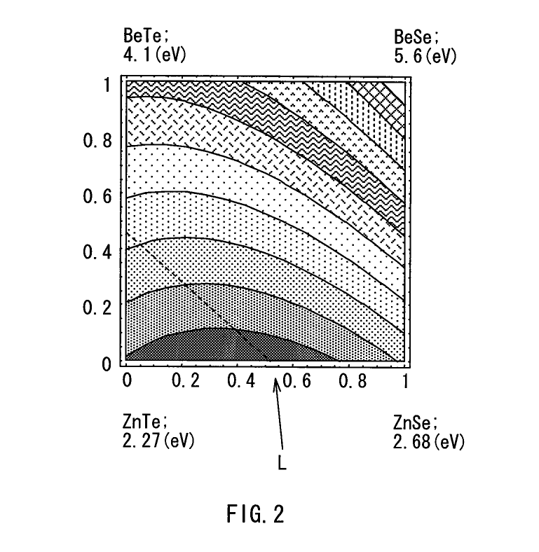

As the material of the p-type cladding layer 13, for example, a BeₓZn₁₋ₓSe_{y}Te_{1-y} mixed crystal (0<x<1, 0<y<1) is cited. FIG. 2 shows results obtained by calculating dependence of Eg (at room temperature) of the quaternary mixed crystal on composition ratios x and y, and a broken line L indicates a composition ratio establishing lattice matching with InP (a lattice constant of 5.869 Å (0.5869 nm)) of which the substrate 11 is made. As various property values used for calculation in FIG. 2, property values described in A. Waag et al., Journal of Crystal Growth, (Netherlands), (Elsevier Science B.V.), 1998, 184/185, No. 1<BeTe lattice constant, BeSe; Eg>, F. J. DiSalvok et al., Physical Review B., American Physical Society, 1995, Vol. 52, 7058<BeSe lattice constant>, A. Waag et al., Journal of Applied Physics, American Institute of Physics, 1997, Vol. 81, p. 451<ZnSe, ZnTe lattice constants>, A. Waag et al., International Symposium on Blue Laser and Light emitting diodes, Chiba Japan Mar. 5-7, 1996, p. 17<BeTe; Eg>, and A. Waag et al., Journal of Crystal Growth, (Netherlands), Elsevier Science B.V., 1996, 159, 54<ZnSe, ZnTe; Eg> are used. In the case where the p-type cladding layer 13 is lattice-matched with InP of which the substrate 11 is made, and the active layer 14 in a green region is taken into consideration, Eg is necessary to be approximately 2.7 eV or over. To satisfy this, it is obvious from FIG. 2 that, for example, the composition ratios x and y are preferably x≧0.3 and y≦0.2, respectively. As described above, the Group II-VI compound semiconductor mixed crystal including tellurium (Te) as a Group VI element can achieve a high p-type carrier concentration, and ZnTe.BeTe also conforms to this. Therefore, when the composition ratio (1-y) of tellurium (Te) is 0.8 or over, a high carrier concentration close to the order of 10 to the 20th power can be obtained, and the improvement in electrical conductivity of the p-type cladding layer 13 can be achieved.

Moreover, the p-type cladding layer 13 is made of a BeZnSeTe mixed crystal, and does not include magnesium (Mg), so material deterioration due to moisture absorption or the like can be prevented, so high material stability can be obtained.

The active layer 14 has a Type II superlattice structure. More specifically, in one layer (an A layer) of the superlattice structure of the active layer 14, an upper end of a valence band is higher than that of the p-type cladding layer 13, and the other layer (a B layer) is made of a mixed crystal having an element structure equivalent to that of the p-type cladding layer 13. Thereby, an effective VBM of the active layer 14 (an upper end of a first quantum level of the valence band in the superlattice structure) is formed at a higher energy level than the VBM (an upper end of a valence band) of a Be_{0.3}Zn_{0.7}Se_{0.2}Te_{0.8} mixed crystal of which the p-type cladding layer 13 is made, and the junction between the active layer 14 and the p-type cladding layer 13 has a Type I structure. Therefore, in the laser diode 10, light-emitting efficiency can be improved. In addition, the B layer may be made of substantially the same elements as those of the mixed crystal of the p-type cladding layer 13. Further, in the case where the same element structure is used, the composition ratio of each element is not necessarily exactly the same.

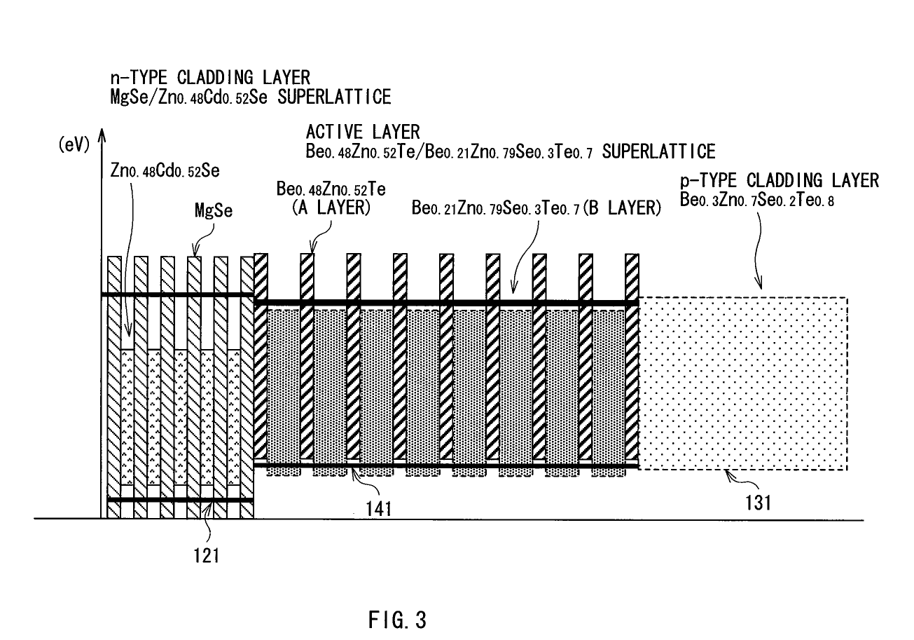

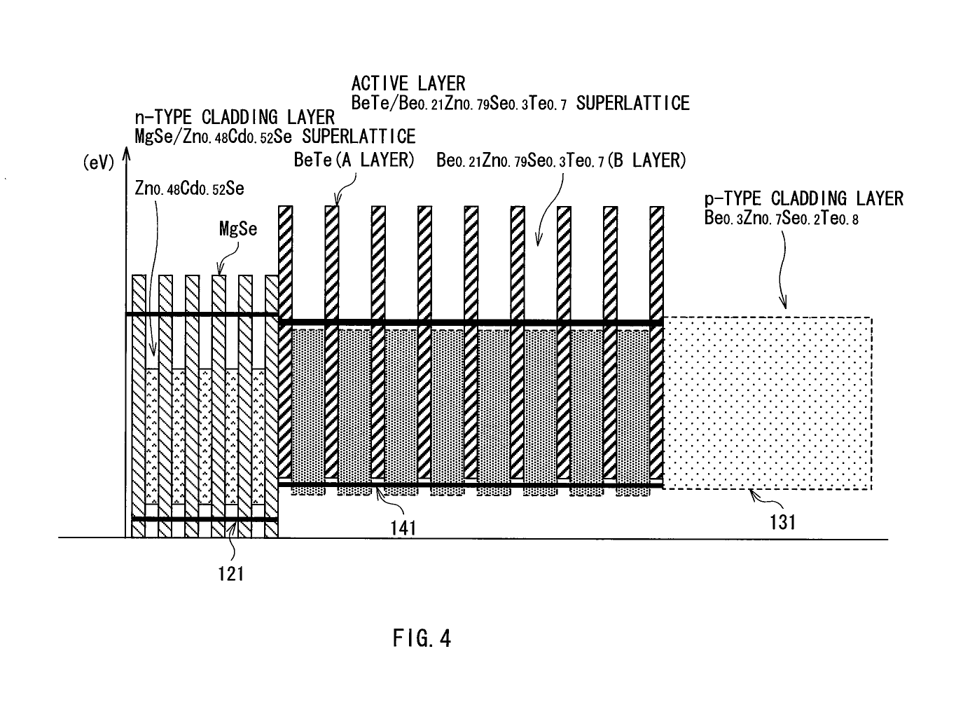

On the other hand, Japanese Unexamined Patent Application Publication No. H04-100292 describes a Group III-V compound semiconductor, and the Group III-V compound semiconductor has a different basic structure from that of the embodiment, and a cladding layer is made of a ternary mixed crystal (for example, in the case of GaAs/GaP, GaAs_{0.5}P_{0.5}) made of binary mixed crystals used in a superlattice active layer, so the band lineup is also different from that in the embodiment. More specifically, as will be described below referring to FIGS. 3 and 4, the VBM of the p-type cladding layer 13 in the embodiment is equivalent to that of the B layer of the active layer 14, and is lower than the VBM of the A layer. On the other hand, in the structure in Japanese Unexamined Patent Application Publication No. H04-100292, the VBM of the p-type cladding layer falls in substantially the midpoint position between the VBMs of two layers of the superlattice active layer, and there is a high possibility that the junction between the active layer and the p-type cladding layer has a Type II structure.

FIG. 3 shows an example of a band structure of a main part of such a laser diode 10. The active layer 14 has, for example, a Type II superlattice structure of Be_{0.48}Zn_{0.52}Te/Be_{0.21}Zn_{0.79}Se_{0.3}Te_{0.7}. Thereby, an effective VBM 141 of the active layer 14 is formed at a higher energy level than an effective VBM 121 in the superlattice structure of the n-type cladding layer 12 and a VBM 131 of a Be_{0.3}Zn_{0.7}Se_{0.2}Te_{0.8} mixed crystal of which the p-type cladding layer 13 is made, and the junctions between the active layer 14 and the n-type cladding layer 12 and between the active layer 14 and the p-type cladding layer 13 each have a Type I structure.

FIG. 4 shows another example of the junction structure of the main part of the laser diode 10. The active layer 14 has a Type II superlattice structure of BeTe/Be_{0.21}Zn_{0.79}Se_{0.3}Te_{0.7}. Also in this case, the effective VBM 141 of the active layer 14 is formed at a higher energy level than the effective VBM 121 in the superlattice structure of the n-type cladding layer 12 and the VBM 131 of the Be_{0.3}Zn_{0.7}Se_{0.2}Te_{0.8} mixed crystal of which the p-type cladding layer 13 is made, and the junctions between the active layer 14 and the n-type cladding layer 12 and between the active layer 14 and the p-type cladding layer 13 each have a Type I structure.

It is suggested in R. G. Dandrea et al., Applied Physics Letters, 1994, Vol. 64, p. 2145 that in BeTe, light emission takes place in indirect transition, and it is suggested in O. Maksimov et al., Applied Physics Letters, 2001, Vol. 79, No. 6, p. 782 that a BeZeTe mixed crystal lattice-matched to InP has an indirect transition. However, the VBM of BeTe is at a Γ point, and the CBM (Conduction Band Minimum) of BeTe is at an X point. Therefore, when the CBM of the B layer of the active layer 14 is at the Γ point, the active layer 14 with the Type II superlattice structure can emit light in direct transition (Γ-Γ).

Moreover, the active layer 14 shown in FIGS. 3 and 4 has a larger composition ratio of tellurium (Te), compared to an active layer in a related art (in the related art, the composition ratio of tellurium (Te) is 0.6, in the embodiment, the composition ratio of tellurium (Te) is 0.8). It is indicated in M. J. S. P. Brasil et al., Applied Physics Letters, 1991, Vol. 58, No. 22, p. 2509 that the larger the composition ratio of tellurium (Te) in the ZnSeTe mixed crystal is (0.65 or over), the smaller the FWHM of a light emission spectrum becomes, and the better the light emission characteristics becomes. In BeZnSeTe, a phenomenon equivalent to that in ZnSeTe is expected, and in the active layer 14 in the embodiment, an improvement in light emission characteristics is expected, compared to the active layer in the related art.

The composition ratio of the B layer of the active layer 14 and the ML number of the A layer/the B layer can be appropriately designed so as to obtain a desired emission wavelength. For example, in the case where a Be_{0.21}Zn_{0.79}Se_{0.3}Te_{0.7} mixed crystal is used, when the A layer/the B layer is approximately 2 to 10/10 to 15 mL, light emission of a wavelength of approximately 530 nm can be obtained.

Moreover, regarding a difference in refractive index, it is suggested in F. C. Peiris et al., Journal of Electronic Materials, 2003, Vol. 32, No. 7 that a BeZnTe mixed crystal is a material having a relatively large refractive index (approximately 3.05 at a wavelength of approximately 550 nm). Therefore, when the p-type cladding layer 13 is made of a BeZnSeTe mixed crystal, and the active layer 14 has a superlattice structure of a BeZnTe mixed crystal (or BeTe)/a BeZnSeTe mixed crystal, the p-type cladding layer 13 has a lower refractive index than the active layer 14, and good optical confinement into the active layer 14 can be achieved.

The light emission characteristics of the Type II superlattice will be described below. A Type II heterojunction has a structure in which electrons and holes are spatially separated, and in general, compared to a Type I structure in which electrons and holes are confined in the same space, it is known that the Type II heterojunction has poor light emission characteristics. However, when the Type II heterojunction has a superlattice structure, and the superlattice structure is a short-period superlattice in which electron and hole wave functions overlap each other, a possibility that the light-emitting efficiency reaches the same level as that of the Type I structure is expected.

The superlattice layer 15 reduces resistance generated by a discrete valence band of the p-type cladding layer 13 and the cap layer 16, and reduces the operation voltage, and the superlattice layer 15 has a multiquantum well structure in which, for example, p-type ZnTe layers which are doped with nitrogen (N) as a p-type impurity and BeZnTe layers which are doped with nitrogen (N) as a p-type impurity are alternately laminated. The cap layer 16 has, for example, a thickness of approximately 10 nm, and is made of ZnTe doped with nitrogen (N) as a p-type impurity.

A part of the p-type cladding layer 13, the superlattice layer 15 and the cap layer 16 forms a thin-strip-shaped ridge (in FIG. 1, a strip-shaped ridge extending in a direction vertical to a paper plane), and a current is injected into a portion corresponding to the ridge of the active layer 14. An insulting layer 17 made of aluminum oxide (Al₂O₃), polyimide or the like is formed on both sides of the ridge on the p-type cladding layer 13. A p-side electrode 21 is formed on the cap layer 16. The p-side electrode 21 has, for example, a configuration in which palladium (Pd), platinum (Pt) and gold (Au) are laminated in order, and is electrically connected to the p-type cladding layer 13 through the cap layer 16 and the superlattice layer 15. An n-side electrode 22 made of, for example, gold-germanium (AuGe), nickel (Ni) and gold (Au) is formed on the back surface of the substrate 11.

Further, in the laser diode 10, a pair of side surfaces which face each other in a resonator direction are a pair of resonator end surfaces, and a pair of reflecting mirror films (not shown) are formed on the pair of resonator end surfaces. One of the reflecting mirror films is adjusted so as to have low reflectivity, and the other reflecting mirror film is adjusted so as to have high reflectivity. Thereby, light emitted from the active layer 14 travels between the reflecting mirror films so as to be amplified, and the amplified light is emitted from the reflecting mirror film with low reflectivity as a laser beam.

For example, the laser diode 10 can be manufactured by the following steps.

At first, for example, the n-type cladding layer 12, the active layer 14, the p-type cladding layer 13, the superlattice layer 15 and the cap layer 16 all of which are made of the above-described materials with the above-described thicknesses are laminated in order on the substrate 11 by a MBE (Molecular Beam Epitaxy) method.

Next, for example, a mask (not shown) made of a resist is formed on the cap layer 16, and parts of the cap layer 16, the superlattice layer 15 and the p-type cladding layer 13 are selectively removed by etching using the mask to form a thin-strip-shaped ridge. Then, the insulating layer 17 made of aluminum oxide is formed on both sides of the ridge by, for example, a vacuum deposition method and a liftoff method.

After the insulating layer 17 is formed, a palladium layer, a platinum layer and a gold layer is formed in order on the cap layer 16 and the insulating layer 17 by, for example, a vacuum deposition method to form the p-side electrode 21. Moreover, on the back surface of the substrate 11, a gold-germanium layer, a nickel layer and a gold layer are formed in order by evaporation to form the n-side electrode 22. After the n-side electrode 22 and the p-side electrode 21 are formed, the substrate 11 is adjusted to have a predetermined size, and the reflecting mirror films (not shown) are formed on a pair of resonator end surfaces facing each other in the length direction of the cap layer 16. Thereby, the laser diode 10 shown in FIG. 1 is formed.

In the laser diode 10, when a predetermined voltage is applied between the n-side electrode 22 and the p-side electrode 21, a current is injected into the active layer 14, and light is emitted by electron-hole recombination. The light is reflected by the pair of reflecting mirror films, and travels between the reflecting mirror films to cause laser oscillation, and the light is emitted to outside as a laser beam. In this case, the active layer 14 has a Type II superlattice structure including the A layer in which the upper end of the valence band is higher than that of the p-type cladding layer 13 and the B layer which is made of a mixed crystal having an element structure equivalent to that of the p-type cladding layer 13, and the effective VBM 141 of the active layer 14 is formed at a higher energy level than the VBM 131 of the Be_{0.3}Zn_{0.7}Se_{0.2}Te_{0.8} of which the p-type cladding layer 13 is made, and the junction between the active layer 14 and the p-type cladding layer 13 has a Type I structure. Therefore, the light-emitting efficiency is improved. Moreover, the p-type cladding layer 13 includes tellurium (Te) as a Group VI element, so the carrier concentration of the p-type cladding layer 13 is increased, so electrical conductivity is improved.

Thus, in the embodiment, the active layer 14 has a Type II superlattice structure, and the junctions between the active layer 14 and the n-type cladding layer 12 and between the active layer 14 and the p-type cladding layer 13 each have a Type I structure, so light-emitting efficiency can be improved. Moreover, the p-type cladding layer 13 includes tellurium (Te) as a Group VI element, so the carrier concentration can be increased, and good electrical characteristics can be achieved.

Although the present invention is described referring to the embodiment, the invention is not limited to the embodiment, and can be variously modified. For example, the material, the thickness, the forming method and the forming conditions of each layer described in the above embodiment are not limited to those described above, and the layer may be made of any other material with any other thickness, and the layer may be formed by any other forming method under any other forming conditions. For example, the material of the p-type cladding layer 13 is not limited to the above-described BeZnSeTe quaternary mixed crystal, and may be a ternary or quaternary mixed crystal made of another Group II-VI compound semiconductor material. Moreover, the p-type cladding layer 13 may have a superlattice structure in which at least one of layers includes tellurium (Te).

Moreover, in the above-described embodiment, the configuration of the laser diode 10 is described referring to specific examples; however, the laser diode 10 does not necessarily include all layers, or may further include any other layer such as a buffer layer.

Further, the invention is applicable to other semiconductor light-emitting devices such as an LED in addition to the laser diode.

It should be understood by those skilled in the art that various modifications, combinations, sub-combinations and alterations may occur depending on design requirements and other factors insofar as they are within the scope of the appended claims or the equivalents thereof.

What is claimed is:

1. A semiconductor light-emitting device made of a Group II-VI compound semiconductor, the semiconductor light-emitting device comprising an active layer between an n-type cladding layer and a p-type cladding layer,
wherein the active layer has a Type II superlattice structure, and the junctions between the active layer and the n-type cladding layer and between the active layer and the p-type cladding layer each have a Type I structure, and the p-type cladding layer includes tellurium (Te) as a Group VI element.

2. The semiconductor light-emitting device according to claim 1, wherein
the p-type cladding layer is a single layer including tellurium (Te).

3. The semiconductor light-emitting device according to claim 1, wherein
in one layer constituting the superlattice structure of the active layer, an upper end of a valence band is higher than that of the p-type cladding layer, and the other layer is made of a mixed crystal having an element structure equivalent to that of the p-type cladding layer.

4. The semiconductor light-emitting device according to claim 1, wherein
at least one of layers constituting the superlattice structure of the active layer is made of a mixed crystal including beryllium (Be).
